(19) United States
(12) Patent Application Publication
(10) Pub. No.: US 2026/0247659 A1
(43) Pub. Date: Aug. 20, 2026

(54) TRANSISTOR DEVICE AND MANUFACTURING METHOD THEREOF

(71) Applicant: ProAsia Semiconductor Corporation, Hsinchu (TW)

(72) Inventors: Meng-Wei Wu, Hsinchu (TW); I-Tai Li, Hsinchu (TW); Chen-Hua Lin, Hsinchu (TW)

(21) Appl. No.: 19/234,833

(22) Filed: Jun. 11, 2025

(30) Foreign Application Priority Data
Feb. 14, 2025 (TW) 114105617

(51) Int. Cl. H10D 30/66; H10D 30/01; H10D 62/13; H10D 62/832; H10D 64/27; H10D 64/68

(52) U.S. Cl. CPC H10D 30/668; H10D 30/0297; H10D 62/154; H10D 62/8325; H10D 64/514; H10D 64/681

(57) ABSTRACT

A transistor device and a manufacturing method thereof are provided. The transistor device includes a silicon carbide substrate, a silicon carbide epitaxial layer, a gate trench, a first conductive type doped body region and a boron ion doped interface. The silicon carbide epitaxial layer is disposed on the silicon carbide substrate. The gate trench is formed in the silicon carbide epitaxial layer, the first conductive type doped body region is adjacent to the sidewall of the gate trench and is disposed on the silicon carbide epitaxial layer, and the boron ion doped interface is disposed between the gate trench and the silicon carbide epitaxial layer.

### CROSS-REFERENCES TO RELATED APPLICATIONS

This application claims the benefit of priority to Taiwanese Patent Application No. 114105617 filed on February 14, 2025, which is hereby incorporated by reference in its entirety.

### BACKGROUND OF THE INVENTION

### Field of the Invention

This invention relates to a transistor device and a manufacturing method thereof, and in particular to a trench gate transistor device and a manufacturing method thereof.

### Description of the Related Art

A Power Metal Oxide Semiconductor Field-Effect Transistor, generally referred to as a Power MOSFET, is a field-effect transistor that can be widely used in analog and digital circuits. It has become the mainstream of power devices, holding a dominant position in the market and is frequently applied in various electronic power applications. The Power MOSFET has a very low on-resistance (Ron), and due to the extremely high gate input impedance of the Power MOSFET, the power dissipation at the input terminal is quite small.

On the other hand, since the trench gate structure can conduct the on-current in the vertical direction, it reduces the surface current crowding effect and effectively shortens the current path, thereby facilitating the reduction of on-resistance. This has led to increasing attention to the application of trench structures in silicon-based MOSFETs. However, ordinary single-trench structures face challenges related to long-term reliability due to electric field concentration at the trench bottom. Furthermore, the switching speed of power MOSFETs primarily depends on the charging and discharging of the gate, with a smaller gate input charge (Qg) resulting in faster switching speed. In other words, the switching time is closely related to the capacitance value in the structure, particularly the charge (Qgd) between the gate and drain. Therefore, how to improve the trench gate power MOSFET structure to reduce on-resistance (Ron) and gate-to-drain charge (Qgd), thereby decreasing on-resistance and enhancing switching speed and other device performances, is an urgent issue to be addressed in the industry.

### SUMMARY OF THE INVENTION

The main objective of this invention is to provide an innovative transistor device, particularly one in which a borosilicate glass layer is filled in the gate trench structure, and boron ions from the borosilicate glass layer diffuse through the trench sidewalls into the silicon carbide substrate. This reduces the defect density of the oxide layer during the subsequent formation of the gate trench oxide layer and produces a high-quality gate oxide layer, thereby reducing on-resistance and enhancing device performance such as switching speed.

To achieve the above objective, this invention provides a transistor device comprising a silicon carbide substrate, a silicon carbide epitaxial layer, a gate trench, a first conductive type doped body region, and a boron ion doped interface. The silicon carbide epitaxial layer is disposed on the silicon carbide substrate, the gate trench is formed in the silicon carbide epitaxial layer, the first conductive type doped body region is adjacent to a sidewall of the gate trench and disposed on the silicon carbide epitaxial layer, and the boron ion doped interface is disposed between the gate trench and the silicon carbide epitaxial layer.

In one embodiment of the transistor device of this invention, the boron ion doped interface has a doping concentration of 1E12 to 1.5E13 (cm⁻³).

In one embodiment of the transistor device of this invention, the boron ion doped interface has a doping thickness of 1 to 1.5 micrometers (µm).

In one embodiment of the transistor device of this invention, the gate trench has a gate oxide layer and a gate polysilicon layer, and the gate oxide layer is sandwiched between the gate polysilicon layer and the boron ion doped interface.

In one embodiment of the transistor device of this invention, the gate oxide layer has a thickness of 500 angstroms (Å).

In one embodiment of the transistor device of this invention, the gate trench has a depth of 1 to 3 micrometers (µm).

In one embodiment of the transistor device of this invention, the transistor device further comprises two second conductive type doped regions, respectively disposed on two sides above the first conductive type doped body region.

To achieve the above objective, this invention provides a manufacturing method of a transistor device, comprising: forming a first conductive type doped body region disposed on a silicon carbide epitaxial layer; forming a gate trench disposed in the silicon carbide epitaxial layer, wherein the first conductive type doped body region is adjacent to a sidewall of the gate trench and disposed on the silicon carbide epitaxial layer; and forming a boron ion doped interface between the gate trench and the silicon carbide epitaxial layer.

In one embodiment of the manufacturing method of the transistor device of this invention, the step of forming a boron ion doped interface comprises: forming a borosilicate glass layer to cover the surface of the gate trench; heating the borosilicate glass layer to diffuse boron contained in the borosilicate glass layer into the silicon carbide epitaxial layer adjacent to the gate trench and forming the boron ion doped interface; and removing the borosilicate glass layer.

In one embodiment of the manufacturing method of the transistor device of this invention, the step of heating the borosilicate glass layer is to increase the temperature to 1000 to 1500°C to diffuse the boron contained in the borosilicate glass layer into the silicon carbide epitaxial layer adjacent to the gate trench and forming the boron ion doped interface.

In one embodiment of the manufacturing method of the transistor device of this invention, the step of forming the boron ion doped interface is to form the boron ion doped interface with a doping concentration of 1E12 to 1.5E13 (cm⁻³).

In one embodiment of the manufacturing method of the transistor device of this invention, the step of forming the boron ion doped interface is to form the boron ion doped interface with a doping thickness of 1 to 1.5 micrometers (µm).

In one embodiment of the manufacturing method of the transistor device of this invention, further comprising: forming a gate oxide layer to cover the boron ion doped interface and then removing a portion of the gate oxide layer on the first conductive type doped body region; and forming a gate polysilicon layer to cover the gate oxide layer in the gate trench and filling the gate trench.

In one embodiment of the manufacturing method of the transistor device of this invention, the step of forming a gate oxide layer is to increase the temperature to 1400 to 1600°C to form the gate oxide layer covering the borosilicate glass layer.

In one embodiment of the manufacturing method of the transistor device of this invention, the step of forming a gate oxide layer is to form the gate oxide layer having a thickness of 500 angstroms (Å).

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1A to FIG. 1K are schematic diagrams illustrating the manufacturing of a power transistor device in one embodiment of this invention; and

FIG. 2 is a flowchart schematic of the power transistor device in one embodiment of this invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

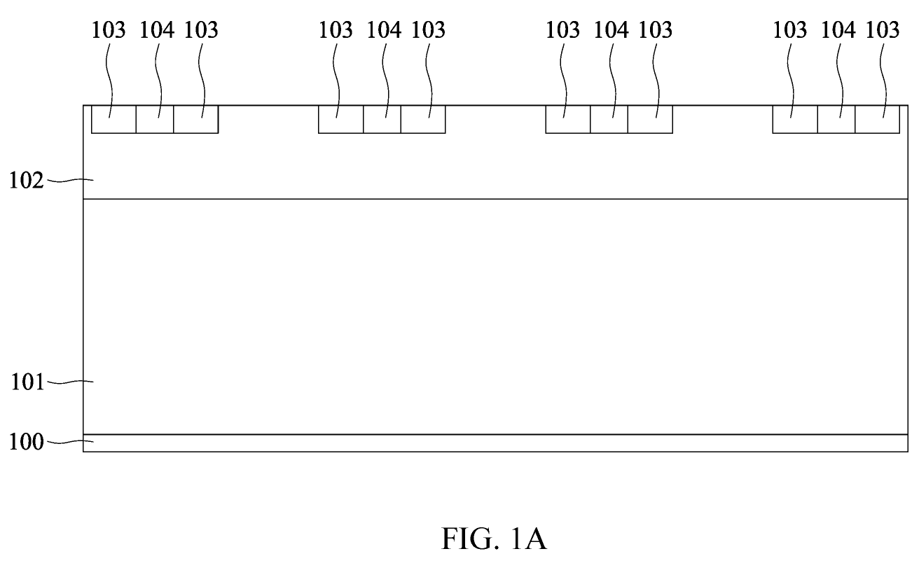

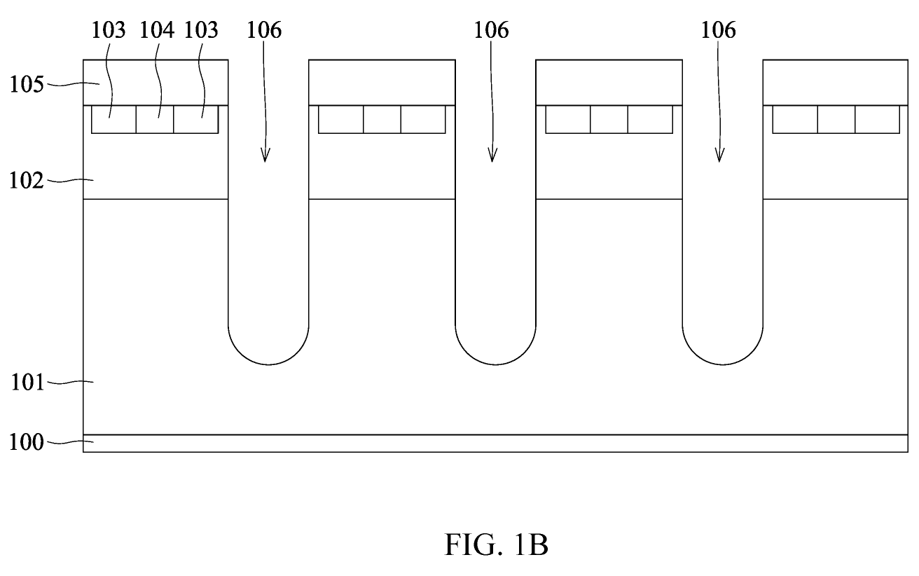

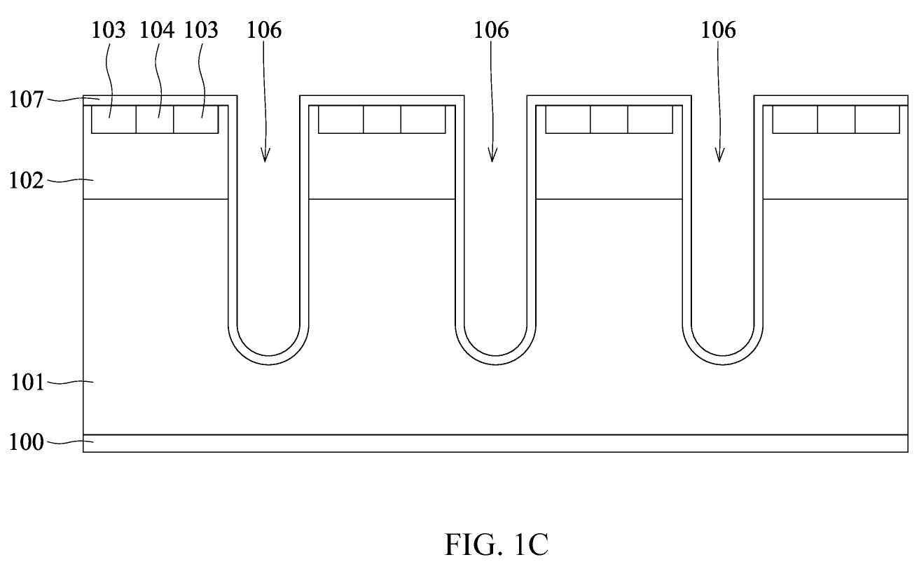

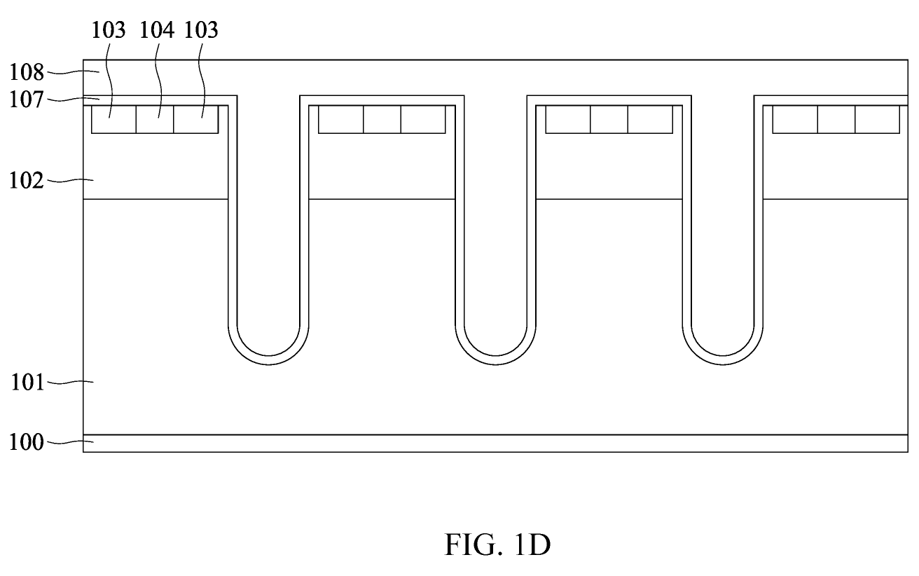

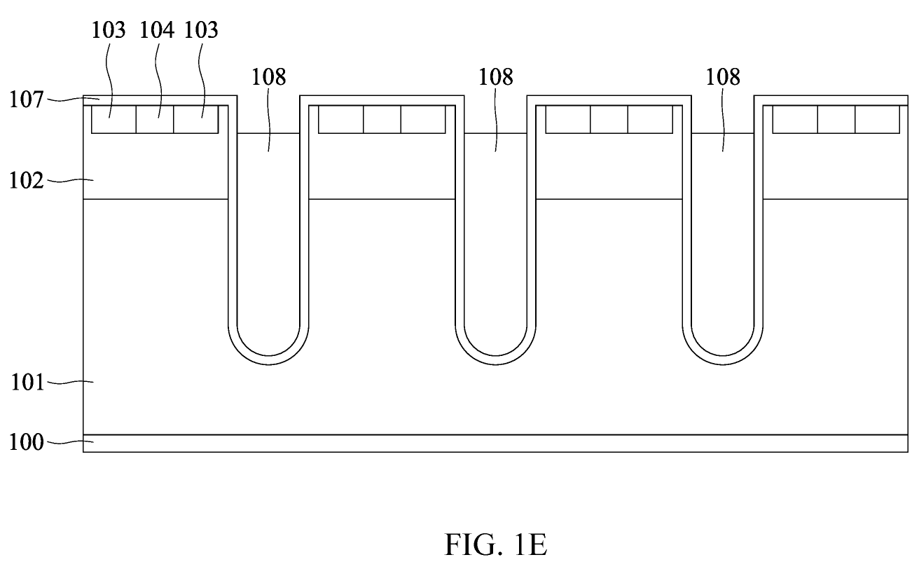

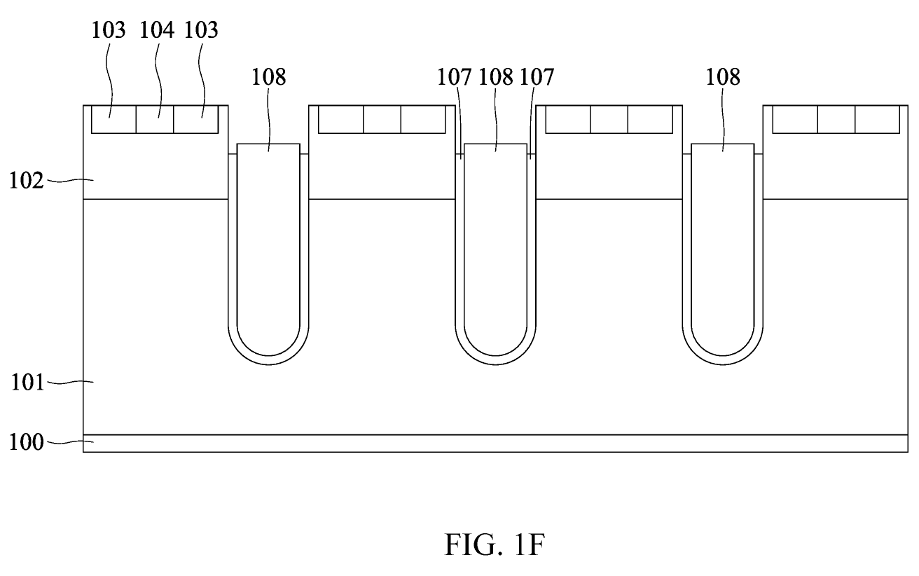

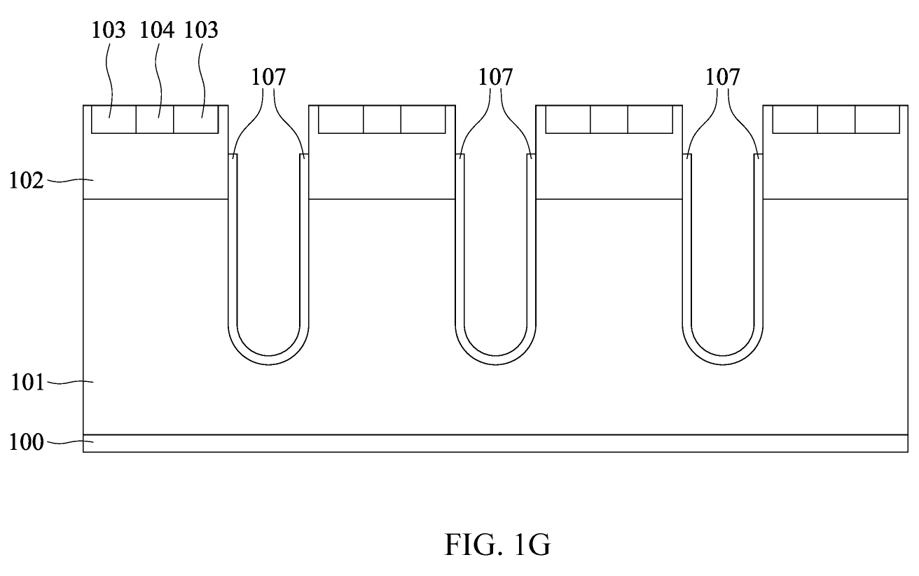

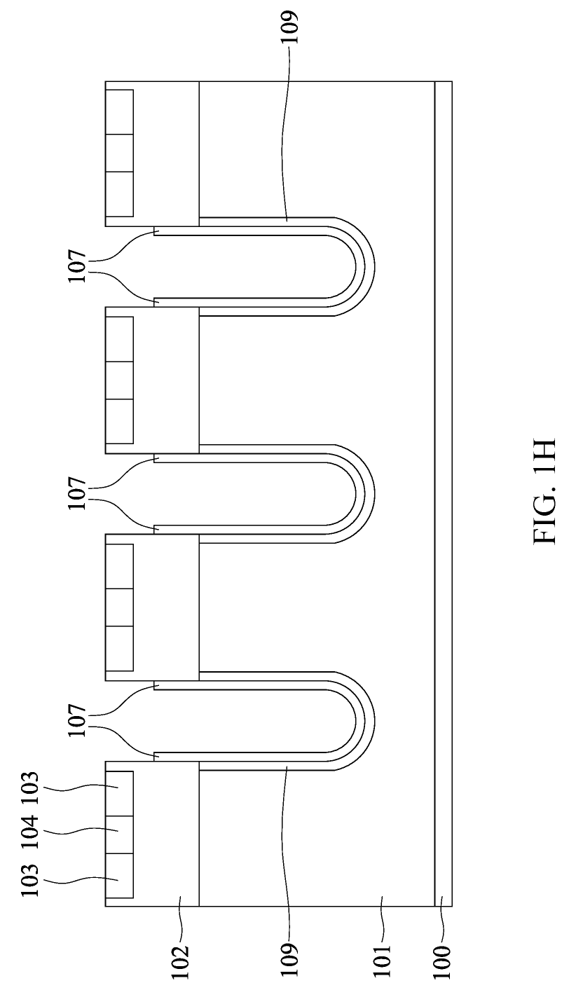

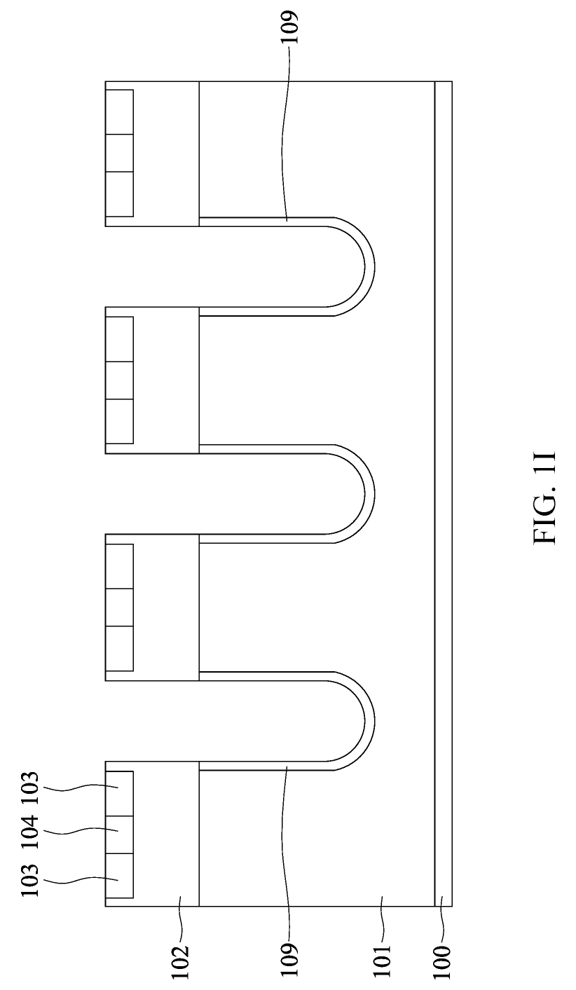

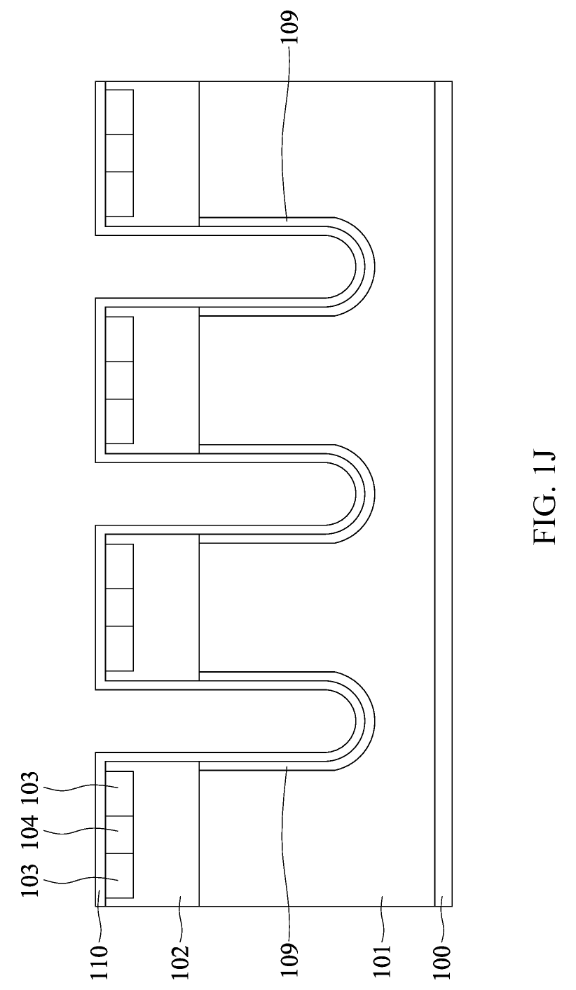

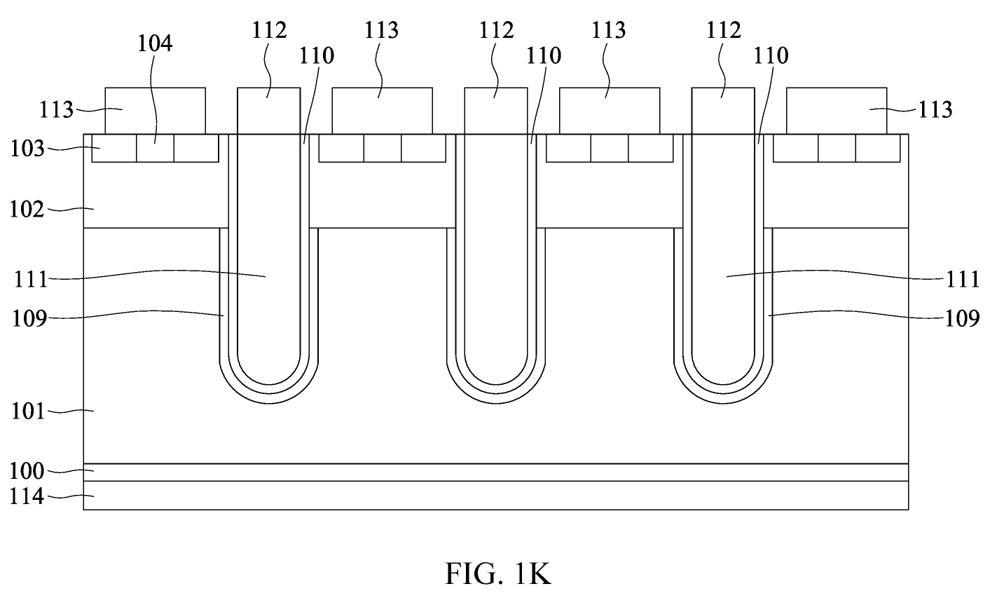

Please refer to FIG. 1A to FIG. 1K together, which show cross-sectional schematic diagrams illustrating the manufacturing of a power transistor device in one embodiment of this invention. Specifically, this power transistor device is a Vertical Diffused Metal Oxide Semiconductor Field-Effect Transistor (VDMOSFET), as detailed below. This power transistor device has a silicon carbide substrate 100, and a silicon carbide epitaxial layer 101 is disposed on the silicon carbide substrate 100. This silicon carbide epitaxial layer 101 may be, but not limited to, an N-type lightly doped silicon carbide epitaxial layer, having a thickness of several micrometers (µm) to tens of micrometers (µm) and a relatively low doping concentration of 1E14 to 1E16 (cm⁻³), used for the power transistor device to withstand high voltages. In specific embodiments, the thickness and doping concentration of this silicon carbide epitaxial layer 101 are designed based on the voltage withstand requirements of the power transistor device.

Next, a plurality of first conductive type doped body regions 102 are formed on the silicon carbide epitaxial layer 101. Specifically, each first conductive type doped body region 102 may be a P-type lightly doped body region with a doping concentration of 1E16 to 1E17 (cm⁻³), which falls within the range of medium to low doping concentration, ensuring sufficient blocking capability for the transistor device in the off state while providing a controllable channel region. Additionally, since the power transistor device in this embodiment is a vertical diffused metal oxide semiconductor field-effect transistor, each first conductive type doped body region 102 further includes two second conductive type doped regions 103, respectively disposed on two sides near the surface of the transistor device above each first conductive type doped body region 102. Specifically, the second conductive type doped region 103 may be an N-type heavily doped region with a doping concentration in the range of 1E19 to 1E20 (cm⁻³), ensuring low resistance to serve as the source region of the power transistor device and forming a good ohmic contact with the source metal. In a preferred embodiment, to further reduce the contact resistance with the metal and suppress the base resistance of the parasitic PNP Bipolar Junction Transistor (BJT), a first conductive type doped region 104 is further provided between the two second conductive type doped regions 103. Specifically, this may be a P-type heavily doped region with a doping concentration in the range of 1E18 to 1E19 (cm⁻³).

Please refer to FIG. 1B, which shows the formation of a patterned photoresist 105 on the device surface to define the pattern of the gate trench structure. Then, using the patterned photoresist 105 as an etching mask, the silicon carbide epitaxial layer 101 is etched to form a trench structure 106 in the silicon carbide epitaxial layer 101, such that the first conductive type doped body region 102 is adjacent to the sidewall of the trench structure 106 and disposed on the silicon carbide epitaxial layer 101. Preferably, this trench structure 106 has a depth of 1 to 3 micrometers (µm) for the subsequent formation of the gate trench, as detailed below. Please refer to FIG. 1C, after removing the patterned photoresist 105, a borosilicate glass (BSG) layer 107 is deposited using plasma-enhanced chemical vapor deposition (PECVD) to cover the surface of the trench structure 106, or alternatively, a boro-phospho-silicate glass (BPSG) layer may be deposited to cover the surface of the trench structure 106.

Next, as shown in FIG. 1D, after filling the trench structure 106 with a photoresist 108, partial etching of the photoresist 108 is performed in a time-controlled manner to an appropriate height within the trench structure 106, exposing the borosilicate glass layer 107 on the surface of the remaining areas outside the trench structure 106, as shown in FIG. 1E. Then, using the photoresist 108 retained in the trench structure 106 as an etching mask, the exposed borosilicate glass layer 107 is removed by wet etching, leaving only the borosilicate glass layer 107 within the trench structure 106, as shown in FIG. 1F. Subsequently, the photoresist 108 within the trench structure 106 is removed, leaving only the borosilicate glass layer 107 on the sidewall of the trench structure, as shown in FIG. 1G.

Please refer to FIG. 1H, a high-temperature furnace process is performed to increase the temperature to 1000 to 1500°C, allowing the boron contained in the borosilicate glass layer 107 to diffuse into the silicon carbide epitaxial layer 101 adjacent to the sidewall of the trench structure, forming a boron ion doped interface 109 between the sidewall of the trench structure and the silicon carbide epitaxial layer 101. In a preferred embodiment, this boron ion doped interface 109 has a doping thickness of 1 to 1.5 micrometers (µm), and the boron ion doped interface 109 has a boron ion doping concentration of 1E12 to 1.5E13 (cm⁻³). Subsequently, the borosilicate glass layer 107 on the sidewall of the trench structure is removed using a buffered oxide etchant (BOE) or buffered hydrofluoric acid (BHF), as shown in FIG. 1I. Next, a high-temperature oxidation film process is performed, for example, by increasing the process temperature to 1400 to 1600°C, to grow a uniform and dense oxide film on the device surface and the sidewall of the trench structure, covering the boron ion doped interface 109, as a gate oxide layer 110, as shown in FIG. 1K. Specifically, this gate oxide layer 110 may have a thickness of 500 angstroms (Å).

Please continue to refer to FIG. 1K, patterned etching is performed to remove the oxide film on the surface (above the first conductive type doped body region 102) of the device, leaving only the gate oxide layer 110 on the sidewall of the trench structure. Then, polysilicon is filled into the trench structure to form a gate polysilicon layer 111, such that the gate oxide layer 110 is sandwiched between the gate polysilicon layer 111 and the boron ion doped interface 109, completing the entire gate trench structure. In specific embodiments, in addition to polysilicon material, metals (such as tungsten or titanium nitride) or a composite stack of metal and polysilicon may also be filled into the trench structure. It should be noted that, due to the presence of a boron ion doped interface 109 between the sidewall of the trench structure and the silicon carbide epitaxial layer 101 in this invention, during the heating process for growing the gate oxide layer 110, boron ions capture defects in the oxide film, reducing and improving the defect density of the oxide layer, optimizing the film quality of the gate oxide layer in the gate trench, and further reducing the on-resistance. Finally, a metallization process is performed, as shown, to form a gate metal 112, a source metal 113, and a drain metal 114 on the transistor device, completing the metal contact process with the gate region, source region, and the backside drain region of the device.

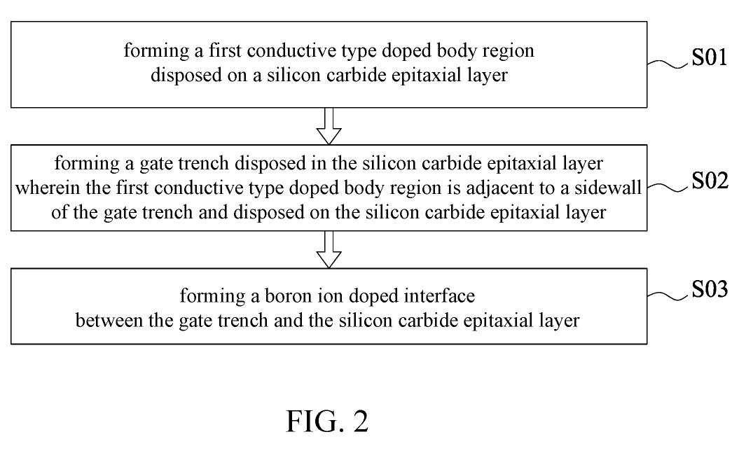

Please refer to FIG. 2, which shows a flowchart schematic of the manufacturing of the power transistor device of this invention. First, in step S01, a first conductive type doped body region is formed to be disposed on a silicon carbide epitaxial layer. In step S02, a gate trench is formed to be disposed in the silicon carbide epitaxial layer, wherein the first conductive type doped body region is adjacent to a sidewall of the gate trench and disposed on the silicon carbide epitaxial layer. Next, in step S03, a boron ion doped interface is formed between the gate trench and the silicon carbide epitaxial layer. The descriptions of the related components in the aforementioned process steps can be referred to the above content and will not be repeated here.

This invention provides an optimized gate trench structure, which not only utilizes the structural advantages of the gate trench to extend the channel region in the vertical direction, increasing the effective channel width and improving the current limiting effect similar to that of a Junction Field-Effect Transistor (JFET) in traditional VDMOSFETs, shortening the electron flow path, but also optimizes the film quality of the gate oxide layer on the sidewall of the trench structure. This further reduces the device size, making the cell structure more compact, allowing more channels to be integrated per unit area, and reducing the on-resistance of the device. In addition, the trench gate structure with excellent gate oxide layer film quality can more effectively control the formation of the depletion layer on the surface of the P-type lightly doped body region, reducing the parasitic effects of the bipolar junction transistor, improving the off-state performance of the device, and reducing leakage current. On the other hand, it can also improve the electric field distribution within the transistor device, reducing local electric field peaks, thereby enhancing the voltage withstand capability.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A transistor device, comprising:
a silicon carbide substrate;
a silicon carbide epitaxial layer disposed on the silicon carbide substrate;
a gate trench disposed in the silicon carbide epitaxial layer;
a first conductive type doped body region adjacent to a sidewall of the gate trench and is disposed on the silicon carbide epitaxial layer; and
a boron ion doped interface disposed between the gate trench and the silicon carbide epitaxial layer.

2. The transistor device of claim 1, wherein the boron ion doped interface has a doping concentration of 1E12 to 1.5E13 (cm⁻³).

3. The transistor device of claim 1, wherein the boron ion doped interface has a doping thickness of 1 to 1.5 micrometers (µm).

4. The transistor device of claim 1, wherein the gate trench has a gate oxide layer and a gate polysilicon layer, and the gate oxide layer is sandwiched between the gate polysilicon layer and the boron ion doped interface.

5. The transistor device of claim 4, wherein the gate oxide layer has a thickness of 500 angstroms (Å).

6. The transistor device of claim 4, wherein the gate trench has a depth of 1 to 3 micrometers (µm).

7. The transistor device of claim 3, further comprising two second conductive type doped regions, respectively disposed on two sides above the first conductive type doped body region.

8. A manufacturing method of a transistor device, comprising:
forming a first conductive type doped body region disposed on a silicon carbide epitaxial layer;
forming a gate trench disposed in the silicon carbide epitaxial layer, wherein the first conductive type doped body region is adjacent to a sidewall of the gate trench and disposed on the silicon carbide epitaxial layer; and
forming a boron ion doped interface between the gate trench and the silicon carbide epitaxial layer.

9. The manufacturing method of a transistor device of claim 8, wherein the step of forming a boron ion doped interface comprises:
forming a borosilicate glass layer to cover the surface of the gate trench;
heating the borosilicate glass layer to diffuse boron contained in the borosilicate glass layer into the silicon carbide epitaxial layer adjacent to the gate trench and forming the boron ion doped interface; and
removing the borosilicate glass layer.

10. The manufacturing method of a transistor device of claim 9, wherein the step of heating the borosilicate glass layer is to increase the temperature to 1000 to 1500°C to diffuse the boron contained in the borosilicate glass layer into the silicon carbide epitaxial layer adjacent to the gate trench and forming the boron ion doped interface.

11. The manufacturing method of a transistor device of claim 9, wherein the step of forming the boron ion doped interface is to form the boron ion doped interface with a doping concentration of 1E12 to 1.5E13 (cm⁻³).

12. The manufacturing method of a transistor device of claim 9, wherein the step of forming the boron ion doped interface is to form the boron ion doped interface with a doping thickness of 1 to 1.5 micrometers (µm).

13. The manufacturing method of a transistor device of claim 9, further comprising:
forming a gate oxide layer to cover the boron ion doped interface and then removing a portion of the gate oxide layer on the first conductive type doped body region; and
forming a gate polysilicon layer to cover the gate oxide layer in the gate trench and filling the gate trench.

14. The manufacturing method of a transistor device of claim 13, wherein the step of forming a gate oxide layer is to increase the temperature to 1400 to 1600°C to form the gate oxide layer covering the borosilicate glass layer.

15. The manufacturing method of a transistor device of claim 13, wherein the step of forming a gate oxide layer is to form the gate oxide layer having a thickness of 500 angstroms (Å).
